(19) United States
(12) Patent Application Publication
(10) Pub. No.: US 2017/0206948 A1
(43) Pub. Date: Jul. 20, 2017

(54) Encoded Global Bitlines for Memory and Other Circuits

(71) Applicant: Broadcom Corporation, Irvine, CA (US)

(72) Inventors: Travis Reynold Hebig, Lakeville, MN (US); Ronald Daniel lsliefson, Lakeville, MN (US); Carl Anthony Monzel, III, Eagan, MN (US); Myron James Buer, Prior Lake, MN (US)

(21) Appl. No.: 15/003,279

(22) Filed: Jan. 21, 2016

Related U.S. Application Data
(60) Provisional application No. 62/280,469, filed on Jan. 19, 2016.

(51) Int. Cl. G11C 11/419

(52) U.S. Cl. CPC G11C 11/419

(57) ABSTRACT

Encoded bitlines run globally through a memory architecture. The encoded bitlines carry an encoded representation of the data bits read from memory cells. As a specific example, the encoded representation may be carried on encoded global bitlines in an SRAM memory architecture. The encoded representation reduces power consumption when used in conjunction with bitline pre-charging or pre-discharging. The encoding technique may be implemented in circuitry other than memories and applied to any type of signal bus, e.g., for address, data, or control signals, running between any types of circuitry.

### PRIORITY CLAIM

This application claims priority to provisional application Ser. No. 62/280,469, filed Jan. 19, 2016, which is entirely incorporated by reference.

### TECHNICAL FIELD

This disclosure relates to bitline encoding, including bitline encoding for memory circuits such as static random access memory (SRAM) circuits.

### BACKGROUND

Rapid advances in electronics and communication technologies, driven by immense customer demand, have resulted in the worldwide adoption of an immense range of electronic devices. Many of these devices receive, store, and process data at significant clock rates, heavily relying on memory storage to do so. With increased clock rates comes increased energy consumption. Reduced energy consumption is often a design goal that is pursued to achieve, as just one example, longer operation on a limited battery charge.

### BRIEF DESCRIPTION OF THE DRAWINGS

FIG. 1 shows SRAM memory architectures.

FIG. 2 shows an SRAM memory architecture with encoded bitlines.

FIG. 3 shows a global bitline encoding for two bits.

FIG. 4 shows a flow diagram of logic for encoding bitlines.

FIG. 5 shows a circuit architecture with encoded bitlines.

### DETAILED DESCRIPTION

The discussion below describes a static random access memory (SRAM) read circuit. The read circuit reduces energy consumption by employing a local sense amplifier with multiple-bit (e.g., two-bit) encoding in the output stage. In addition, the read circuit includes a ‘m’-input to ‘n’-output (e.g., four-input to two-output) decoding global sense amplifier. The sense amplifier is responsive to encoded low-swing global bitlines driven by the output stage.

While the discussion below focuses primarily on the use of encoded bitlines in a memory architecture, encoded bitlines may be used in other circuits. That is, the encoded bitline techniques described below may be added to any type of circuitry that carries data on individual bitlines. As one example, a data bus between a processor and an interface port (e.g., a PCIe port) may encode, transfer, and decode encoded data over the bitlines, data lines, or data buses between the processor and the interface port.

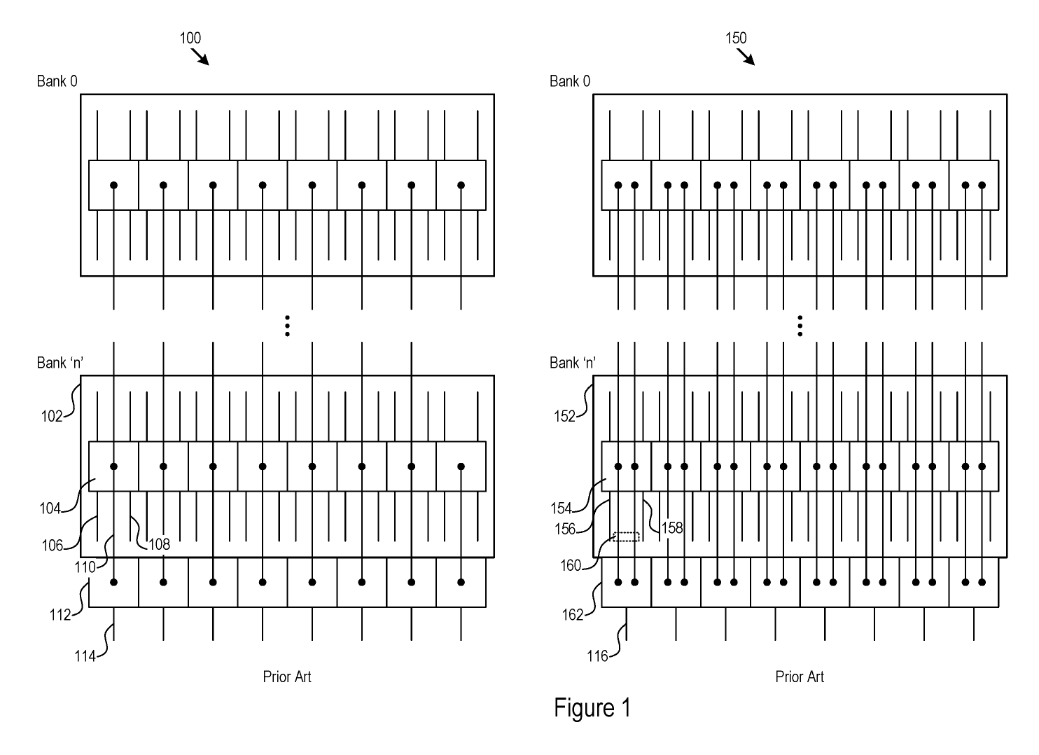

FIG. 1 shows example SRAM memory architectures 100 and 150. In the architectures 100 and 150, banks of SRAM cells (e.g., the bank ‘n’ 102 and the bank ‘n’ 152), are stacked to form large memory arrays. FIG. 1 is for purposes of illustration only, and the encoded bitline techniques described below do not require multiple banks for operation. There may be any number of banks in an array, and as just one example range, between 1 and 16.

Within the banks are individual SRAM memory cells with local sense circuitry, e.g., the local sense circuitry 104 and 154. Locally, the memory cells may adhere to an architecture with bitline negative (BL*) lines (e.g., 106, 156) and bitline positive (BL) lines (e.g., 108, 158) to drive and read data into cross coupled inverters that hold the data in each memory cell.

In the architecture 100 the memory cells output their data on a single-ended global output bitline, e.g., the single-ended global output bitline 110. In contrast, in the architecture 150, the memory cells output their data on differential global output bitlines, e.g., the differential global output bitlines 160. Accordingly, the architecture 100 includes global sense circuitry 112 that receive the single-ended data, and drive the single-ended output line 114, e.g., to other connected circuitry. The architecture 150 includes global sense circuitry 162 that receives the differentially communicated data on the differential global output bitlines 160, and that drives the single-ended output line 116 accordingly.

As a specific example, the memory cells may be 6T SRAM memory cells. In 6T cells, a read is performed by activating a word line in one of the banks, and then activating a local sense circuit within the bank. The local sense circuitry drives the global bitlines to global sense circuitry, which in turn drives a (typically) single-ended output from the memory array. In many typical use cases, the global bitlines consume nearly 50% of the total dynamic read power consumption of the memory array.

Table 1, below, shows normalized dynamic power consumption of the architecture 100.

TABLE 1

| Data state for | Normalized dynamic power consumption |
|---|---|
| two bits | Full swing single ended global bitlines |
| 0 0 | 2 Units: |
| | Pre-charge: 1 1 |
| | Final: 0 0 |
| 0 1 | 1 Unit: |
| | Pre-charge: 1 1 |
| | Final: 0 1 |
| 1 0 | 1 Unit: |
| | Pre-charge: 1 1 |
| | Final: 1 0 |
| 1 1 | 0 Units: |
| | Pre-charge: 1 1 |
| | Final: 1 1 |
| Average | 1 Unit |

The left most column shows the data state of two bits of data. Note that during a read operation, the global bitlines 110 are typically pre-charged. In this single-ended example, pre-charging involves charging the global bitlines 110 to substantially the supply voltage Vdd, while discharging the global bitlines 110 involves driving the global bitlines to substantially Vss, e.g., ground.

To output two bits of data from the memory array that are 00, the architecture 100 pre-charges and then discharges two global bitlines. That is, the two global bitlines transition from a fully charged state to a fully discharged state, consuming two units of power, as shown in Table 1. Similarly, to output the 01 or the 10 state, both global bitlines are fully charged, and one global bitline is fully discharged; the other global bitline remains pre-charged and does not transition. Table 1 shows these operations consuming one unit of power. To output the 11 state, both global bitlines are pre-charged, and both remain pre-charged, consuming no dynamic power. Accordingly, Table 1 shows zero units of power in the right column. The average power consumption of outputting two bits of data across all four possible data states is 1 unit of power. Expressed another way, the four possible combinations of bits cause four discharge events or state transitions starting from the full pre-charged state: two for output 00, one for output 01, one for output 10, and zero for output 11.

Table 2, below, shows normalized dynamic power consumption of the architecture 150.

TABLE 2

| Data state for | Normalized dynamic power consumption |
|---|---|
| two bits | Low swing differential global bitlines |
| 0 0 | 1 (0.5 + 0.5) Unit: |
| | Pre-charge: 1 1 1 1 |
| | Final: 0 1 0 1 |
| 0 1 | 1 (0.5 + 0.5) Unit: |
| | Pre-charge: 1 1 1 1 |
| | Final: 0 1 1 0 |
| 1 0 | 1 (0.5 + 0.5) Unit: |
| | Pre-charge: 1 1 1 1 |
| | Final: 1 0 0 1 |
| 1 1 | 1 (0.5 + 0.5) Unit: |
| | Pre-charge: 1 1 1 1 |
| | Final: 1 0 1 0 |
| Average | 1 Unit |

As in Table 1, the left most column shows the data state of two bits of data. For the architecture 150 it is assumed that during a read operation, the global bitlines 160 are differential, and are pre-charged in a low-swing manner, e.g., to Vdd/2 or another pre-defined fraction of Vdd, so that a bit transition does not cause a full discharge of the supply voltage or a full charge of the supply voltage. That is, for the differential global bitlines in the architecture 150, pre-charging involves charging the global bitlines 110 to a portion of the supply voltage, e.g., Vdd/2, while discharging the global bitlines 110 involves driving the global bitlines 110 to substantially Vss, e.g., ground. In other implementations, low-swing encoding may include charging the global bitlines to Vdd, and discharging them to Vdd/2 or another fraction of Vdd.

Note that two pairs of differential global bitlines 160 carry the data in this example, one pair per global sense amplifier 162. To output two bits of data from the memory array that are 00, the architecture 150 low-swing pre-charges all four global bitlines, and then discharges two global bitlines. That is, two global bitlines transition from a partially charged state to a fully discharged state, consuming 0.5 units of power each (one unit of power in total), as shown in Table 2. Similarly, to output the 01 or the 10 state, all four global bitlines are low-swing pre-charged, and two global bitlines are fully discharged. Table 2 shows these operations consuming one unit of power. Similarly, to output the 11 state, all four global bitlines are low-swing pre-charged, and two transition to fully discharged states, consuming one unit of power as noted in Table 2. The average power consumption of outputting two bits of data across all four possible data states is again 1 unit of power. As with the example shown in Table 2 above, the four possible combinations of bits cause eight low-swing discharge events starting from the low-swing pre-charged state: two for output 00, two for output 01, two for output 10, and two for output 11.

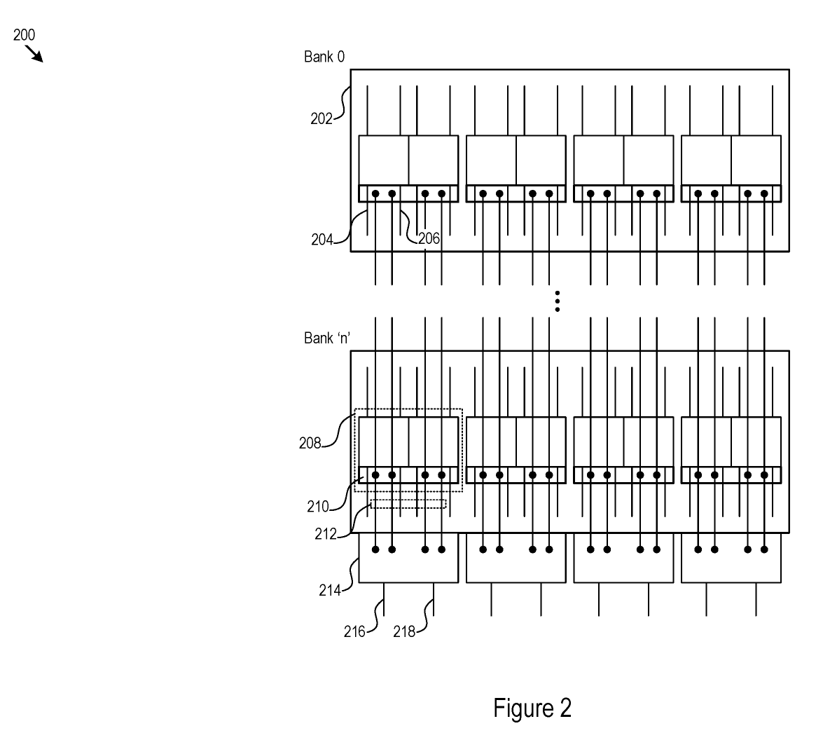

FIG. 2 shows an SRAM memory architecture 200 with encoded bitlines. The architecture 200 includes banks of SRAM cells (e.g., the bank 202) stacked to form a larger memory array. Within the banks are individual SRAM memory cells with bitline negative (BL*) lines (e.g., 204) and bitline positive (BL) lines (e.g., 206) to drive and read data into cross coupled inverters or other storage elements that hold the data in each memory cell. The memory cell bitlines are coupled to local sense circuitry, e.g., the local sense circuitry 208.

Note that the local sense circuitry includes bitline encoder circuitry, e.g., the bitline encoder circuitry 210. Further, in the architecture 200, the memory cells output their data on multiple pairs of encoded global output bitlines, e.g., the pairs of encoded global output bitlines 212. These pairs form an encoded output that carries encoded representations of the input bits read from the individual memory cells. In one implementation, the encoded global output bitlines are low-swing bitlines, e.g., pre-charged to Vdd, and discharged to Vdd/2.

The architecture 200 also includes global sense circuitry 214 that receives the encoded representations on the encoded output, and drive the single-ended output lines that are connected circuitry. In this example, the global sense circuitry 214 will convert the encoded representation into two individual single-ended bit outputs, e.g., the bit output 216 and the bit output 218. As noted above, the memory cells may be 6T SRAM memory cells. A read is performed by activating a word line in one of the banks, and then activating the local sense circuit, including encoder circuitry, within the bank. The local sense circuitry drives the global bitlines with an encoded output to the global sense circuitry, which in turn drives single-ended outputs from the memory array.

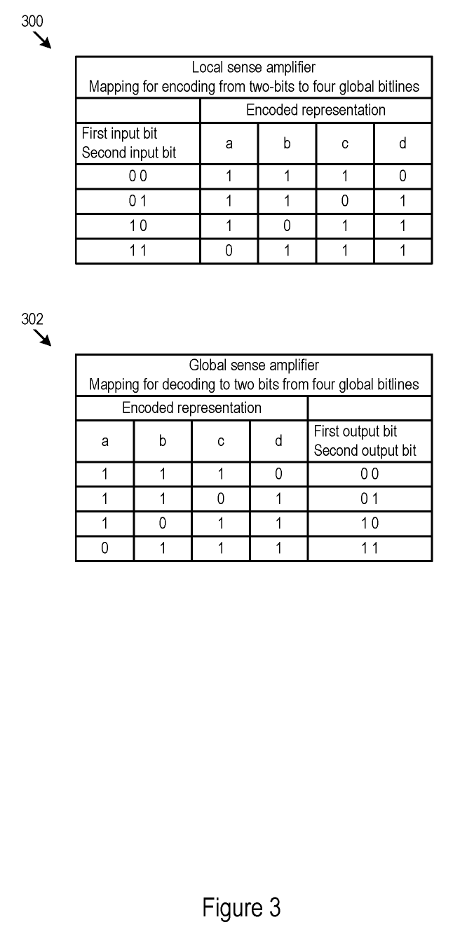

In this example, the architecture 200 uses two-bit encoding to map a first input bit and a second input bit of data (read from the memory cells) into four one-hot low swing dynamic global bitlines. The encoding is done such that a transition of one of the four global bitlines corresponds to one of four possible states of the two bits of data. FIG. 3 shows the encoding 300, which is also shown in Table 3, below.

TABLE 3

| Data state for | Global bitline logical state, pre-charged global bitlines | | | |
|---|---|---|---|---|
| two bits | a | b | c | d |
| 0 0 | 1 | 1 | 1 | 0 |
| 0 1 | 1 | 1 | 0 | 1 |
| 1 0 | 1 | 0 | 1 | 1 |
| 1 1 | 0 | 1 | 1 | 1 |

The global sense circuitry 214 implements a four-input to two-output decoder, with the decoding 302 shown in FIG. 3, and shown below in Table 4.

TABLE 4

| | |
|---|---|
| Encoded representation on global bitlines | Global sense |

| a | b | c | d | circuitry output |
|---|---|---|---|---|
| 1 | 1 | 1 | 0 | 0 0 |
| 1 | 1 | 0 | 1 | 0 1 |
| 1 | 0 | 1 | 1 | 1 0 |
| 0 | 1 | 1 | 1 | 1 1 |

Tables 3 and 4 assume pre-charged bitlines. The encoding technique applies to pre-discharged bitlines as well, as shown in the encoding in Table 5 below. Note that, for pre-charged bitlines, the encoded representation causes fewer discharge events than the differentially defined bits would cause on differentially encoded global bitlines. In implementations with pre-discharged bitlines, the encoded representation causes fewer charge events than the differentially defined bits would cause on differentially encoded global bitlines.

TABLE 5

| Data state for | Global bitline logical state, pre-discharged global bitlines | | | |
|---|---|---|---|---|
| two bits | a | b | c | d |
| 0 0 | 0 | 0 | 0 | 1 |
| 0 1 | 0 | 0 | 1 | 0 |
| 1 0 | 0 | 1 | 0 | 0 |
| 1 1 | 1 | 0 | 0 | 0 |

Table 6, below, shows normalized dynamic power consumption of the architecture 200 in the rightmost column, compared with the two architectures 100 and 150.

TABLE 6

| | Normalized dynamic power consumption, pre-charged global bitlines | | |
|---|---|---|---|
| Data state | Full swing single | Low swing differential | Low swing encoded |
| for two bits | ended global bitlines | global bitlines | global bitlines |
| 0 0 | 2 Units: | 1 (0.5 + 0.5) Unit: | 0.5 Units: |
| | Pre-charge: 1 1 | Pre-charge: 1 1 1 1 | Pre-charge: 1 1 1 1 |
| | Final: 0 0 | Final: 0 1 0 1 | Final: 1 1 1 0 |
| 0 1 | 1 Unit: | 1 (0.5 + 0.5) Unit: | 0.5 Units: |
| | Pre-charge: 1 1 | Pre-charge: 1 1 1 1 | Pre-charge: 1 1 1 1 |
| | Final: 0 1 | Final: 0 1 1 0 | Final: 1 1 0 1 |
| 1 0 | 1 Unit: | 1 (0.5 + 0.5) Unit: | 0.5 Units: |
| | Pre-charge: 1 1 | Pre-charge: 1 1 1 1 | Pre-charge: 1 1 1 1 |
| | Final: 1 0 | Final: 1 0 0 1 | Final: 1 0 1 1 |
| 1 1 | 0 Units: | 1 (0.5 + 0.5) Unit: | 0.5 Units: |
| | Pre-charge: 1 1 | Pre-charge: 1 1 1 1 | Pre-charge: 1 1 1 1 |
| | Final: 1 1 | Final: 1 0 1 0 | Final: 0 1 1 1 |
| Average | 1 Unit | 1 Unit | 0.5 Units |

In the architecture 200, low-swing pre-charge to Vdd and discharge to Vdd/2 is used on the global bitlines (and other low-swing ranges may be employed in other implementations). Regardless of whether the global bitlines are pre-charged or pre-discharged, in each of the four data states (for two bits read from memory), one global bitline of each of the four encoded global bitlines (e.g., the encoded global output bitlines 212) changes charge state. For pre-charged global bitlines, the charge state transition is from a Vdd level to Vdd/2 and the other global bitlines in the encoded group stay at the pre-charged level. Each set of encoded global output bitlines consumes 0.5 units of power to carry the encoded representation, regardless of the two bit inputs.

Note that for the two data bit example, each encoded group of global bitlines includes four global bitlines to carry an encoding that represents the data state of the two data bits. The power consumed by the state transition after pre-charge to represent the two data bits read from the memory cells is 0.5 units of power, because there is a single state transition (e.g., one-hot) with the encoding shown in Tables 3 and 5. The average power consumption of two bits of data across all four possible data states is 0.5 units of power.

The architecture 200 reduces global bitline dynamic power by 50% over other architectures. In large SRAMs, global bitline power can account for up to 50% of the total dynamic power of the memory. As a result, the architecture 200 reduces total dynamic power by 25% when low-swing (e.g., Vdd/2) switching is used on the global bitlines. In some implementations, as little as 100 mV of signal margin may be used on the global bitlines to provide an even greater power reduction, e.g., total dynamic power reduction of 30% or more.

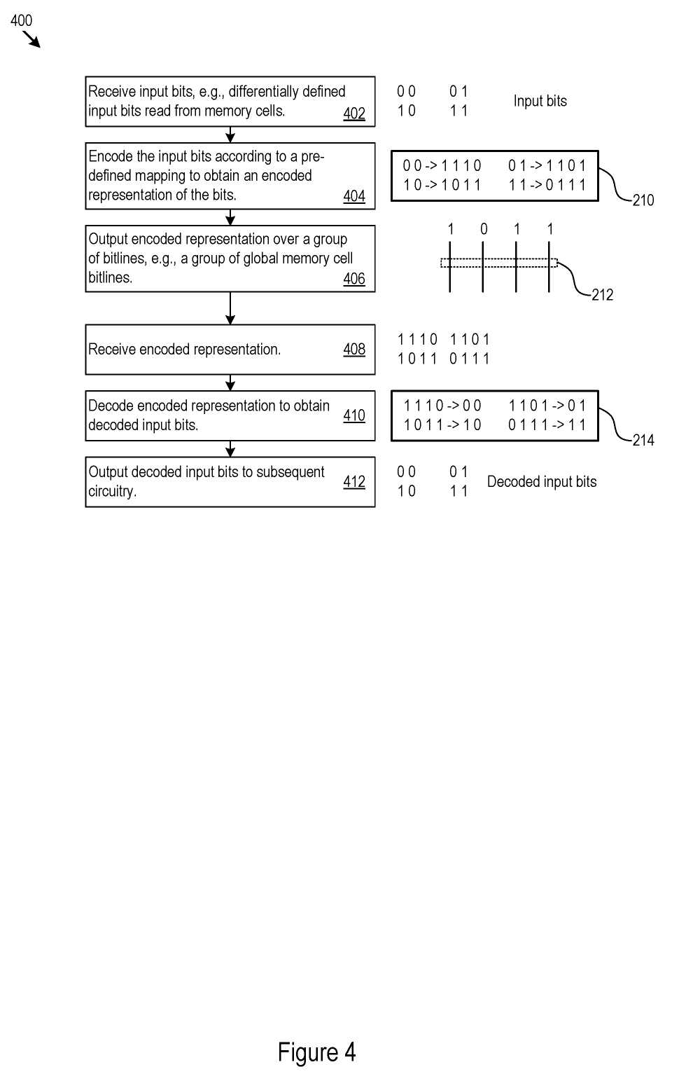

FIG. 4 shows a flow diagram of logic 400 for encoding and decoding bitlines. The logic 400 may be implemented in any circuitry connected to bitlines, data lines, or data buses, including memories, devices on communication buses that run between devices, data paths between or internal to individual integrated circuits or multi-chip modules, or in other configurations.

The logic 400 includes receiving inputs bits (402), e.g., differentially defined bits read from memory cells. The logic 400 encodes the input bits according to a pre-defined mapping to obtain an encoded representation of the bits (404). The encoded representation is carried over a pre-determined number of bitlines in a group, e.g., 4 global bit lines that carry a 4-bit encoded representation of two bits of data. The logic 400 then outputs the encoded representation over the group of bitlines (406). The group of bitlines may be, as examples, low-swing encoded pre-charged global memory cell bitlines, or data bus lines between devices.

A receiving circuit receives the encoded representation (408). For example, the receiving circuit may be global sense circuitry in a memory array, or a bus interface circuit in communication with a data bus. The receiving circuit decodes the encoded representation (410), and outputs the decoded input bits to subsequent circuitry (412).

Expressed another way with regard to memory architectures, the bitline encoding is implemented in circuitry that includes first memory cell connections configured to differentially define a first input bit, and second memory cell connections configured to differentially define a second input bit. The local sensing may be differential or single-ended sensing, however. The circuitry also includes encoding circuitry with an encoded output. The encoding circuitry is configured to receive the first input bit, receive the second input bit, and map the first input bit and the second input bit to a pre-defined encoded representation. The circuitry outputs the pre-defined encoded representation on the encoded output.

In a memory architecture, the first memory cell connections and the second memory cell connections may be local sense amplifier outputs, e.g., SRAM sense amplifier outputs. When the encoded output is a pre-charged output, the pre-defined encoded representation includes fewer discharge states than fully differentially representing the first input bit and second input bit on a set of outputs. When the encoded output is a pre-discharged output, the pre-defined encoded representation includes fewer charge states than fully differentially representing the first input bit and second input bit on a set of outputs. Decoding circuitry receives the encoded output, determines the first input bit and the second input bit from the encoded output, and communicates the first input bit and the second input bit as individual data bits on a decoded output.

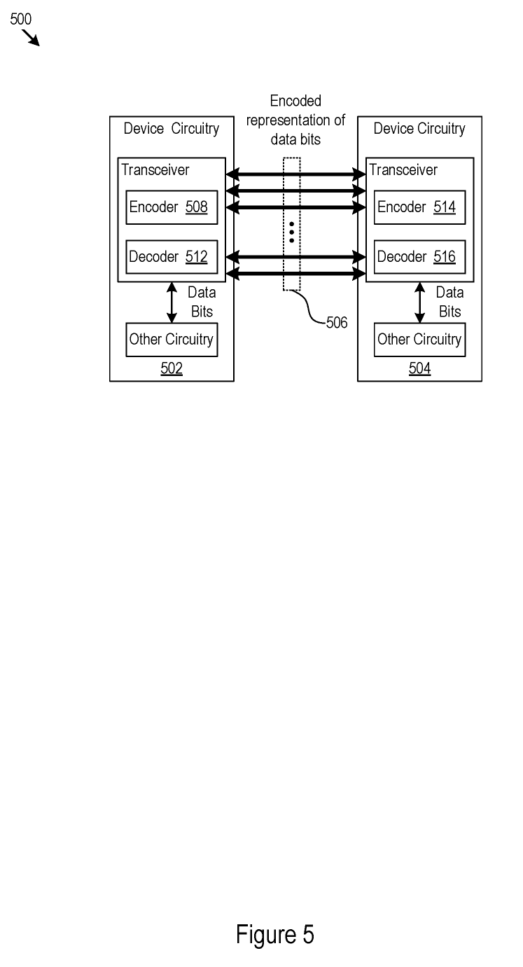

FIG. 5 shows a circuit architecture 500 with encoded bitlines. The circuit architecture 500 illustrates first device circuitry 502 in communication with second device circuitry 504 over a data bus. The data bus may include, for instance, a low-swing encoded pre-charged set of bitlines 506 that carries data between any instances of device circuitry. The device circuitry 502 includes an encoder 508 and a decoder 510, while the device circuitry 504 includes an encoder 512 and a decoder 514. The encoders 508, 514 encode data bits used by other device circuitry into encoded representations and transmit the encoded representations over the data bus. The decoders 512, 516 receive and decode the encoded representations and output the decoded data bits to the other circuitry in the device.

Said another way, the bitline encoding techniques described above may be implemented in many different types of circuits, systems, and devices. Examples include instruction processors, such as a Central Processing Unit (CPU), microcontroller, or a microprocessor; Application Specific Integrated Circuits (ASIC), Programmable Logic Device (PLD), or Field Programmable Gate Array (FPGA). The encoding techniques may be used with memory bitlines, data lines, and data buses and other types of signal lines (e.g., for address, control, and data signals) that connect discrete interconnected hardware components on a printed circuit board, or that connect components manufactured on a single integrated circuit die, distributed among multiple integrated circuit dies, or implemented in a Multiple Chip Module (MCM) of multiple integrated circuit dies in a common package, as examples.

Note also that the bitline encoding techniques described above are not limited to two-input bit to four-output bit encoding. Any number of input bits may be mapped to an encoded representation with fewer discharge events, in the case of bitline pre-charging, or fewer charge events, in the case of bitline pre-discharging. Table 7 provides an example of mapping three input bits to an eight-bit encoded representation with one state transition. Table 8 provides an example of mapping four input bits to a 16-bit encoded representation with a single state transition.

TABLE 7

| Data state | | | | | | | | |
|---|---|---|---|---|---|---|---|---|
| for three | Global bitline logical state, pre-charged global bitlines | | | | | | | |
| bits | a | b | c | d | e | f | g | h |
| 0 0 0 | 1 | 1 | 1 | 1 | 1 | 1 | 1 | 0 |
| 0 0 1 | 1 | 1 | 1 | 1 | 1 | 1 | 0 | 1 |
| 0 1 0 | 1 | 1 | 1 | 1 | 1 | 0 | 1 | 1 |
| 0 1 1 | 1 | 1 | 1 | 1 | 0 | 1 | 1 | 1 |
| 1 0 0 | 1 | 1 | 1 | 0 | 1 | 1 | 1 | 1 |
| 1 0 1 | 1 | 1 | 0 | 1 | 1 | 1 | 1 | 1 |
| 1 1 0 | 1 | 0 | 1 | 1 | 1 | 1 | 1 | 1 |
| 1 1 1 | 0 | 1 | 1 | 1 | 1 | 1 | 1 | 1 |

TABLE 8

| Data | | | | | | | | | | | | | | | | |
|---|---|---|---|---|---|---|---|---|---|---|---|---|---|---|---|---|
| state for | Global bitline logical state, pre-charged global bitlines | | | | | | | | | | | | | | | |
| four bits | a | b | c | d | e | f | g | h | i | j | k | l | m | n | o | p |
| 0 0 0 0 | 1 | 1 | 1 | 1 | 1 | 1 | 1 | 1 | 1 | 1 | 1 | 1 | 1 | 1 | 1 | 0 |
| 0 0 0 1 | 1 | 1 | 1 | 1 | 1 | 1 | 1 | 1 | 1 | 1 | 1 | 1 | 1 | 1 | 0 | 1 |
| 0 0 1 0 | 1 | 1 | 1 | 1 | 1 | 1 | 1 | 1 | 1 | 1 | 1 | 1 | 1 | 0 | 1 | 1 |
| 0 0 1 1 | 1 | 1 | 1 | 1 | 1 | 1 | 1 | 1 | 1 | 1 | 1 | 1 | 0 | 1 | 1 | 1 |
| 0 1 0 0 | 1 | 1 | 1 | 1 | 1 | 1 | 1 | 1 | 1 | 1 | 1 | 0 | 1 | 1 | 1 | 1 |
| 0 1 0 1 | 1 | 1 | 1 | 1 | 1 | 1 | 1 | 1 | 1 | 1 | 0 | 1 | 1 | 1 | 1 | 1 |
| 0 1 1 0 | 1 | 1 | 1 | 1 | 1 | 1 | 1 | 1 | 1 | 0 | 1 | 1 | 1 | 1 | 1 | 1 |
| 0 1 1 1 | 1 | 1 | 1 | 1 | 1 | 1 | 1 | 1 | 0 | 1 | 1 | 1 | 1 | 1 | 1 | 1 |
| 1 0 0 0 | 1 | 1 | 1 | 1 | 1 | 1 | 1 | 0 | 1 | 1 | 1 | 1 | 1 | 1 | 1 | 1 |
| 1 0 0 1 | 1 | 1 | 1 | 1 | 1 | 1 | 0 | 1 | 1 | 1 | 1 | 1 | 1 | 1 | 1 | 1 |
| 1 0 1 0 | 1 | 1 | 1 | 1 | 1 | 0 | 1 | 1 | 1 | 1 | 1 | 1 | 1 | 1 | 1 | 1 |
| 1 0 1 1 | 1 | 1 | 1 | 1 | 0 | 1 | 1 | 1 | 1 | 1 | 1 | 1 | 1 | 1 | 1 | 1 |
| 1 1 0 0 | 1 | 1 | 1 | 0 | 1 | 1 | 1 | 1 | 1 | 1 | 1 | 1 | 1 | 1 | 1 | 1 |
| 1 1 0 1 | 1 | 1 | 0 | 1 | 1 | 1 | 1 | 1 | 1 | 1 | 1 | 1 | 1 | 1 | 1 | 1 |
| 1 1 1 0 | 1 | 0 | 1 | 1 | 1 | 1 | 1 | 1 | 1 | 1 | 1 | 1 | 1 | 1 | 1 | 1 |
| 1 1 1 1 | 0 | 1 | 1 | 1 | 1 | 1 | 1 | 1 | 1 | 1 | 1 | 1 | 1 | 1 | 1 | 1 |

Tables 3, 5, 7, and 8 provide examples of single transition encoding. Other encoded representations may include multiple bitline transitions, with the goal to save power in comparison to a fully differential representation. These encoded representations may be implemented for any number of input bits. Table 9 provides one such example of an encoded representation of three input bits to six encoded global bitlines. Encoded representations that are a multiple of two bits wide may be useful to build on top of memory architectures that already fabricate two differential global bitlines per data bit.

TABLE 9

| Data state for | Global bitline logical state, pre-charged global bitlines | | | | | | |
|---|---|---|---|---|---|---|---|
| three bits | a | b | c | d | e | f | Power Consumption |
| 0 0 0 | 1 | 1 | 1 | 1 | 1 | 0 | 0.5 units |
| 0 0 1 | 1 | 1 | 1 | 1 | 0 | 1 | 0.5 units |
| 0 1 0 | 1 | 1 | 1 | 0 | 1 | 1 | 0.5 units |
| 0 1 1 | 1 | 1 | 0 | 1 | 1 | 1 | 0.5 units |
| 1 0 0 | 1 | 0 | 1 | 1 | 1 | 1 | 0.5 units |
| 1 0 1 | 0 | 1 | 1 | 1 | 1 | 1 | 0.5 units |
| 1 1 0 | 0 | 0 | 1 | 1 | 1 | 1 | 1 unit |
| 1 1 1 | 1 | 0 | 0 | 1 | 1 | 1 | 1 unit |

The encoding in Table 9 uses, on average, ⅝th of a unit of power for data transmission, compared to 1.5 units for a fully differential representation on the global bitlines.

Several example implementations of bitline encoding have been specifically described. However, many other implementations are also possible.

What is claimed is:

1. A circuit comprising:
a first memory cell connection configured to carry a first input bit;
a second memory cell connection configured to carry a second input bit; and
encoding circuitry comprising an encoded output, the encoding circuitry configured to:
receive the first input bit from the first memory cell;
receive the second input bit from the second memory cell;
map the first input bit and the second input bit to a pre-defined encoded representation; and
output the pre-defined encoded representation on the encoded output.

2. The circuit of claim 1, where:
the first memory cell connection, the second memory cell connection, or both comprise sense amplifier outputs.

3. The circuit of claim 1, where:
the first memory cell connection, the second memory cell connection, or both comprise static random access memory (SRAM) sense amplifier outputs.

4. The circuit of claim 1, where:
the encoding circuitry comprises a two input, four output encoder.

5. The circuit of claim 1, where:
the encoded output comprises pre-charged bitlines; and
the pre-defined encoded representation comprises fewer discharge states than a differential representation of the first input bit and second input bit on the encoded output.

6. The circuit of claim 1, where:
the encoded output comprises pre-discharged bitlines; and
the pre-defined encoded representation comprises fewer charge states than a differential representation of the first input bit and second input bit on the encoded output.

7. The circuit of claim 1, where:
the encoding circuitry comprises a two input, four output encoder configured to produce a single state transition on the four outputs for the pre-defined encoded representation.

8. The circuit of claim 1, further comprising:
decoding circuitry comprising a decoded output, the decoding circuitry configured to:
receive the encoded output;
determine the first input bit and the second input bit from the encoded output; and
communicate the first input bit and the second input bit as individual data bits on the decoded output.

9. The circuit of claim 1, where:
the encoded output comprises a low-swing encoded output.

10. The circuit of claim 1, where:
the encoded output comprises low-swing encoded global memory cell bitlines.

11. A method comprising:
receiving differentially defined bits from memory cells;
encoding the differentially defined bits according to a pre-defined mapping to obtain an encoded representation of the bits; and
outputting the encoded representation on global memory cell bitlines in communication with the memory cells.

12. The method of claim 11, where:
outputting comprises outputting the encoded representation on low-swing encoded global memory cell bitlines.

13. The method of claim 11, where:
the global memory cell bitlines comprise pre-charged bitlines; and
the encoded representation causes fewer discharge transitions than differentially communicating the differentially defined bits.

14. The method of claim 11, where:
the global memory cell bitlines comprise pre-discharged bitlines; and
the encoded representation causes fewer charge states than differentially communicating the differentially defined bits.

15. The method of claim 11, where:
the encoding comprises single state transition encoding.

16. The method of claim 11, where:
encoding comprises two input, four output encoding onto the global memory cell bitlines according to the following mapping of the differentially defined bits to the encoded representation:

| Differentially | Encoding on the global memory cell bitlines | | | |
|---|---|---|---|---|
| defined bits | a | b | c | d |
| 0 0 | 1 | 1 | 1 | 0 |
| 0 1 | 1 | 1 | 0 | 1 |
| 1 0 | 1 | 0 | 1 | 1 |
| 1 1 | 0 | 1 | 1 | 1 |

17. The method of claim 11, further comprising:
decoding the encoded representation to determine the bits; and
outputting the bits responsive to a read operation on a memory array that includes the memory cells.

18. A circuit comprising:
memory cells;
encoders coupled to pairs of the memory cells and comprising two-input to four-output low-swing encoded global bitline outputs; and
decoders coupled to the low-swing encoded global bitline outputs and comprising four-input to two-output data connections.

19. The circuit of claim 18, where:
the encoders are configured to map bit inputs from the memory cells to single a transition encoded representations of the bit inputs.

20. The circuit of claim 18, where:
the low-swing encoded global bitline outputs comprise pre-charged or pre-discharged outputs;
the encoders comprise differentially encoded inputs for receiving bit inputs from the memory cells; and
the encoders are configured to map the bit inputs from the memory cells to an encoded representation of the bit inputs that comprises fewer charge transition states than a differential representation of the bit inputs.
